(19) United States
(12) Patent Application Publication
(10) Pub. No.: US 2025/0316950 A1
(43) Pub. Date: Oct. 9, 2025

(54) OPTOELECTRONIC PACKAGING STRUCTURE AND ELECTRONIC DEVICE

(71) Applicant: LITE-ON TECHNOLOGY CORPORATION, TAIPEI CITY (TW)

(72) Inventors: Yu-Chou Lin, New Taipei City (TW); CHEN-HSIU LIN, NEW TAIPEI CITY (TW); Kai-Chieh Liang, New Taipei City (TW)

(21) Appl. No.: 19/244,627

(22) Filed: Jun. 20, 2025

Related U.S. Application Data
(63) Continuation-in-part of application No. 18/634,247, filed on Apr. 12, 2024.
(60) Provisional application No. 63/459,378, filed on Apr. 14, 2023.
(60) Provisional application No. 63/693,850, filed on Sep. 12, 2024.

(30) Foreign Application Priority Data
Mar. 1, 2024 (CN) 202420400926.9
Dec. 30, 2024 (CN) 202423284213.X

(51) Int. Cl. H01S 5/02208; H01S 5/02257; H01S 5/026

(52) U.S. Cl. CPC H01S 5/02208; H01S 5/02257; H01S 5/0262

(57) ABSTRACT

An electronic device includes a transparent cover and an optoelectronic packaging structure. The optoelectronic packaging structure includes a substrate, a sensing component, a light-emitting component, a first partition wall, and an encapsulation structure. The first partition wall is located between the sensing component and the light-emitting component. The encapsulation structure covers the sensing component, the light-emitting component, and the first partition wall. A portion of a top surface of the encapsulation structure defines a first light-transmissive window and a second light-transmissive window. A first groove structure and a second groove structure corresponding to the light-emitting component and the sensing component are formed within the regions of the first light-transmissive window and the second light-transmissive window, respectively.

### CROSS-REFERENCE TO RELATED PATENT APPLICATION

The present disclosure claims the benefit of priority to China Patent Application No. 202420400926.9, filed on Mar. 1, 2024, and No. 202423284213.X, filed on Dec. 30, 2024, in the People's Republic of China. The entire content of the above identified application is incorporated herein by reference.

The present disclosure claims the benefit of priorities to the U.S. Provisional Patent Application Ser. No. 63/459,378, filed on Apr. 14, 2023, Ser. No. 63/693,850 filed on Sep. 12, 2024, which application is incorporated herein by reference in its entirety.

The present disclosure is a Continuation-In-Part of the U.S. patent application Ser. No. 18/634,247, filed on Apr. 12, 2024, and entitled “OPTOELECTRONIC DEVICE,” now pending, the entire disclosures of which are incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an optoelectronic packaging structure and an electronic device, and more particularly to a miniaturized optoelectronic packaging structure and an electronic device that improve signal-to-noise ratio.

### BACKGROUND OF THE DISCLOSURE

Optical physiological sensors generally include a light-emitting unit and a sensing unit. A light emitted by the light-emitting unit as a forward light source, is reflected by an object to be measured (e.g., a human body) and then received by the sensing unit. In this way, the optical physiological sensors sense the physiological characteristics of the human body by comparing signal differences. Generally speaking, a light-blocking wall or a housing is placed between the light-emitting unit and the sensing unit to prevent the light emitted by the light-emitting unit from being directly received by the sensing unit, which could cause premature sensing and affect the accuracy of the sensing result.

However, for small wearable electronic devices, such as TWS Bluetooth® earphones or smart watches, have internal optical physiological sensor equipped with glass. In the limited space of the wearable electronic device, the glass is attached to a top surface of the optical physiological sensor. The configuration of the glass alters the light path due to diffraction, causing undesired light, i.e., so-called stray light, to enter the sensor, thereby generating crosstalk and affecting the product reliability.

### SUMMARY OF THE DISCLOSURE

In response to the above-referenced technical inadequacy, the present disclosure provides a miniaturized optoelectronic packaging structure and an electronic device that improve the signal-to-noise ratio.

In order to solve the above-mentioned problems, one of the technical aspects adopted by the present disclosure is to provide an optoelectronic packaging structure, which includes a substrate, and a sensing component, a light-emitting component, a first partition wall, and an encapsulation structure that are disposed on the substrate. The sensing component and the light-emitting component are arranged along a first direction. The first partition wall is located between the sensing component and the light-emitting component. The first partition wall extends along a second direction. The encapsulation structure covers the sensing component, the light-emitting component, and the first partition wall. A portion of a top surface of the encapsulation structure defines a first light-transmissive window and a second light-transmissive window. The first light-transmissive window and the second light-transmissive window have a first groove structure and a second groove structure. The first groove structure and the second groove structure correspond to the light-emitting component and the sensing component, respectively. The first groove structure and the second groove structure are formed within regions of the first light-transmissive window and the second light-transmissive window, respectively, such that the encapsulation structure includes a non-planar top surface.

In order to solve the above-mentioned problems, another one of the technical aspects adopted by the present disclosure is to provide an optoelectronic packaging structure, which includes a substrate, and a sensing component, a light-emitting component, a first partition wall, and an encapsulation structure that are disposed on the substrate. The sensing component and the light-emitting component are arranged along a first direction. The first partition wall is located between the sensing component and the light-emitting component. The first partition wall extends along a second direction. The encapsulation structure includes a first packaging part and a second packaging part. The sensing component and the light-emitting component are encapsulated within the first packaging part, a portion of the second packaging part forms an annular perimeter wall surrounding the first packaging part, the sensing component, the light-emitting component, and the first partition wall, and another portion of the second packaging part forms a second partition wall stacked above the first partition wall. The first partition wall and the second partition wall jointly divide the first packaging part into a first portion and a second portion. A portion of a top surface of the first packaging part is exposed by the second packaging part and defines a first light-transmissive window and a second light-transmissive window. The first light-transmissive window and the second light-transmissive window correspond to the light-emitting component and the sensing component, respectively. The first light-transmissive window and the second light-transmissive window form a first groove structure and a second groove structure, respectively. A vertical distance is defined between the exposed portion of the top surface of the first packaging part and a top surface of the second packaging part. A maximum predetermined height is defined between the top surface of the second packaging part and a bottom surface of the substrate. The vertical distance is 5% to 40% of the maximum predetermined height.

In order to solve the above-mentioned problems, yet another one of the technical aspects adopted by the present disclosure is to provide an optoelectronic packaging structure, which includes a substrate, and a sensing component, a light-emitting component, a first partition wall, and an encapsulation structure that are disposed on the substrate. The sensing component and the light-emitting component are arranged along a first direction. The first partition wall is located between the sensing component and the light-emitting component. The first partition wall extends along a second direction. The encapsulation structure includes a first packaging part and a second packaging part. The first packaging part covers the sensing component and the light-emitting component. A portion of the second packaging part forms an annular perimeter wall to surround and directly contact the first packaging part and the first partition wall, and another portion of the second packaging part forms a second partition wall stacked above the first partition wall. The first partition wall and the second partition wall jointly divide the first packaging part into a first portion and a second portion. The encapsulation structure includes a non-planar top surface. A portion of a top surface of the first packaging part exposed by the second packaging part defines a first light-transmissive window and a second light-transmissive window. The first light-transmissive window and the second light-transmissive window correspond to the light-emitting component and the sensing component, respectively. A width of the second partition wall in the first direction is greater than a width of the first partition wall in the first direction.

In order to solve the above-mentioned problems, yet another one of the technical aspects adopted by the present disclosure is to provide an electronic device. The electronic device includes a transparent cover and an optoelectronic packaging structure. The optoelectronic packaging structure and the transparent cover are spaced apart from each other by a gap.

Therefore, in the optoelectronic packaging structure provided by the present disclosure, by forming the non-planar structure (i.e., a groove structure) on the top surface of the encapsulation structure, and utilizing an air gap created by the groove structure to extend the light path, the distance between the light-emitting component and the sensing component and the transparent cover such as the glass is increased. This helps to reduce the probability of stray light entering the sensor, minimizes crosstalk, and ultimately improves product reliability. In addition, by designing the first horizontal distance, the distance between the light-emitting component and the edge of the light-transmissive window can be controlled to ensure that the light-emitting component is not too far from the blocking wall structure that are composed of the first partition wall and the second partition wall, thereby preventing the light emitted from the first light-transmissive window from diffracting upon contacting the transparent cover (e.g., the glass) before reaching the object to be detected, causing some light to prematurely enter the second light-transmissive window and be received by the sensing component, thereby affecting the accuracy of the sensing results.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of an optoelectronic packaging structure according to a first embodiment of the present disclosure;

FIG. 2 is a partial schematic exploded view of the optoelectronic packaging structure according to the first embodiment of the present disclosure;

FIG. 3 is a schematic top view of the optoelectronic packaging structure according to the first embodiment of the present disclosure;

FIG. 4 is a schematic cross-sectional view taken along line IV-IV of FIG. 3;

FIG. 5 is a schematic cross-sectional view of another implementation of the optoelectronic packaging structure according to the first embodiment of the present disclosure;

FIG. 6 is a schematic cross-sectional view of yet another implementation of the optoelectronic packaging structure according to the first embodiment of the present disclosure;

FIG. 7 is a schematic top view of an optoelectronic packaging structure according to a second embodiment of the present disclosure;

FIG. 8 is a schematic cross-sectional view taken along line VIII-VIII of FIG. 7; and

FIG. 9 is a curve diagram showing the test result of the optoelectronic packaging structure according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

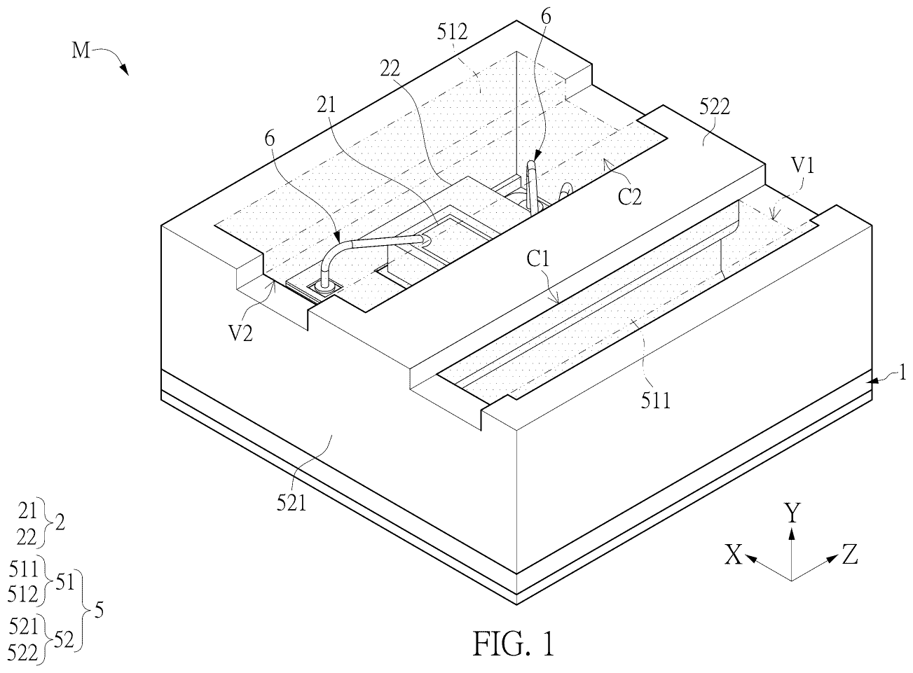

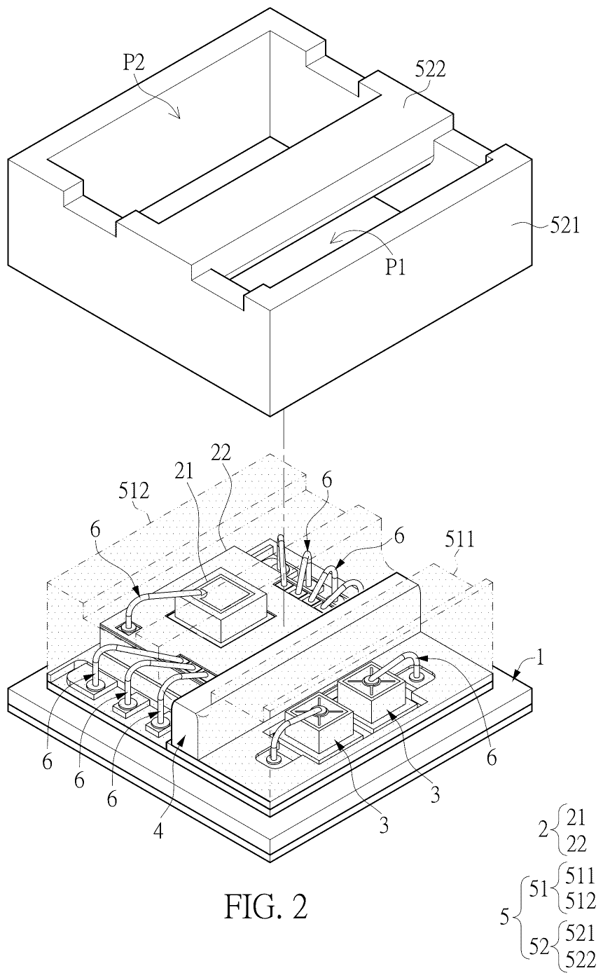

Reference is made to FIG. 1 and FIG. 2. FIG. 1 is a schematic perspective view of an optoelectronic packaging structure according to a first embodiment of the present disclosure. FIG. 2 is a partial schematic exploded view of the optoelectronic packaging structure according to the first embodiment of the present disclosure. The first embodiment of the present disclosure provides an optoelectronic packaging structure M, which includes a substrate 1, a sensing component 2, a light-emitting component, a first partition wall 4, and an encapsulation structure 5.

For example, the optoelectronic packaging structure M of the present disclosure is an optical sensor that is used to sense human physiological characteristics. The substrate 1 can be a circuit board with conductive traces, on which the sensing component 2, the light-emitting component, the first partition wall 4, and the encapsulation structure 5 are disposed. The optoelectronic packaging structure M can be applied in wearable devices such as true wireless stereo (TWS) earphones, augmented reality (AR) devices, virtual reality (VR) devices, and mixed reality (MR) devices, but the present disclosure is not limited thereto.

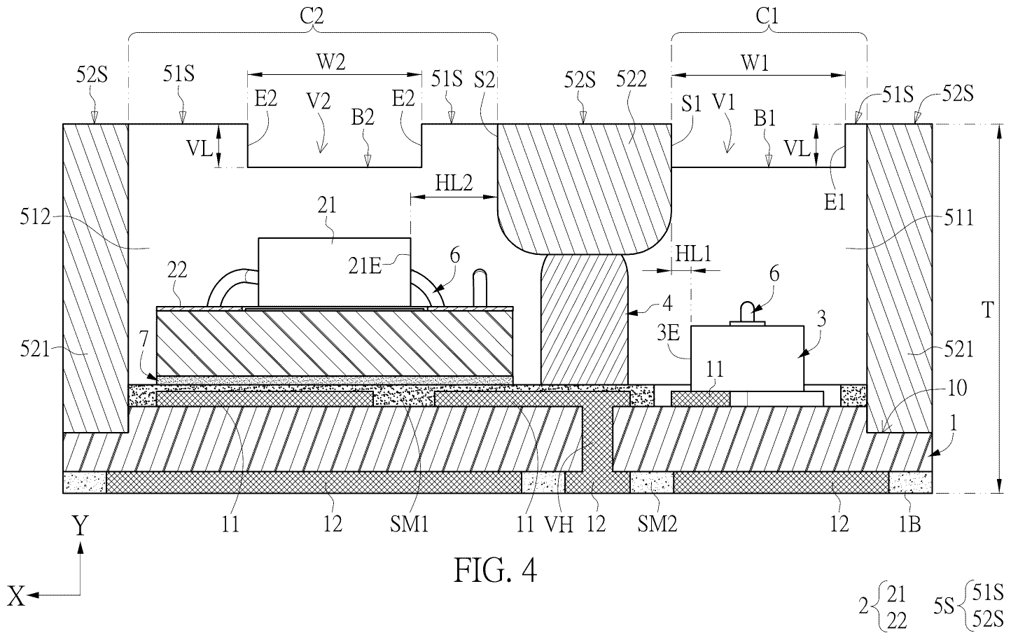

Referring to FIG. 4, the substrate 1 has an upper surface and a lower surface that is opposite to the upper surface. The substrate 1 includes a plurality of first bonding pads 11 and a plurality of second bonding pads 12. The plurality of first bonding pads 11 are disposed on the upper surface of the substrate 1, while the plurality of second bonding pads 12 are disposed on the lower surface of the substrate 1. The plurality of first bonding pads 11 are electrically connected to the plurality of second bonding pads 12 through conductive vias VH. The substrate 1 further includes a first solder mask layer SM1 and a second solder mask layer SM2. The first solder mask layer SM1 is disposed on the upper surface of the substrate 1, and some of the first bonding pads 11 are exposed from the first solder mask layer SM1 to form uncoated regions, such as pads. The second solder mask layer SM2 is disposed on the lower surface of the substrate 1. It should be noted that the configuration of the solder mask layer is not limited in the present disclosure, and any design that achieves electrical insulation for preventing short circuits falls within the spirit and scope of the present disclosure. In the first embodiment, the sensing component 2 and the light-emitting component are electrically connected to the plurality of second bonding pads 12 through the first bonding pads 11 respectively.

The light-emitting component can be one or more light-emitting elements 3. The light-emitting elements 3 can be, for example, light-emitting diodes (LEDs), laser diodes, or various combinations thereof, which are capable of emitting light of different wavelengths, such as infrared, ultraviolet, or visible light, for detection by the sensing component 2. The light-emitting component and the sensing component 2 are arranged along a first direction (i.e., an X-axis direction), with the first partition wall 4 located between the light-emitting component and the sensing component 2. In the present disclosure, the light-emitting component includes two light-emitting elements 3 that are arranged along a second direction (i.e., a Z-axis direction) to emit near-infrared light with wavelengths between 700 nm and 1500 nm. The arrangement or quantity of the light-emitting elements 3, and the color or wavelength of light emitted by the light-emitting elements 3, are not limited in the present disclosure.

The light-emitting component (i.e., the two light-emitting elements 3) can emit light to a surface of an external object (e.g., a surface of human skin), and the light is then reflected back and received by the sensing component 2. The light is converted into an electrical signal by the sensing component 2 to detect changes in the object's state (e.g., the physiological state of the human body).

The sensing component 2 includes a sensing element 21 and a carrier 22. The carrier 22 is bonded to the substrate 1 using an adhesive 7. The carrier 22 can electrically connect the sensing element 21 to the exposed first bonding pads 11 (i.e., the uncoated regions) on the substrate 1 through its internal traces or contact structure, so as to achieve signal transmission. The carrier 22 carries the sensing element 21, which can be a controller, a processor, a memory, an application-specific integrated circuit (ASIC), or analog front end (AFE) IC components. The sensing element 21 can be a photodetector, a phototransistor (PTR), a photo diode, or a photo IC. The sensing element 21 and the carrier 22, as well as the carrier 22 and the first bonding pads 11 (i.e., the uncoated regions), can be electrically connected by a plurality of bonding wires 6. Additionally, the light-emitting element 3 can also be electrically connected to the substrate 1 through bonding wires 6. In other embodiments, the light-emitting element 3 can be mounted to the substrate 1 by flip-chip bonding.

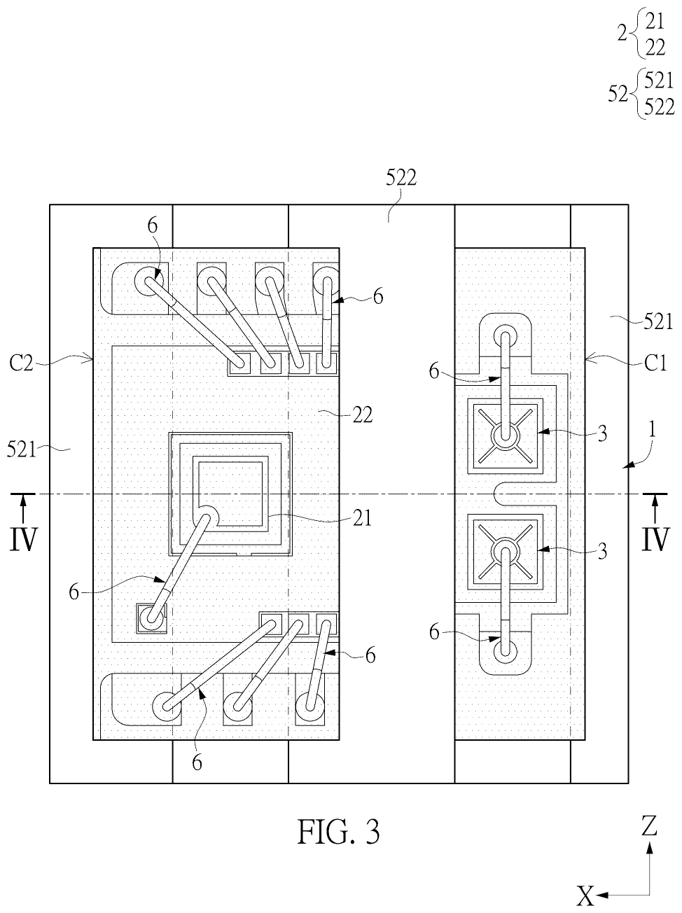

Reference is made to FIGS. 1, 3, and 4. FIG. 3 is a schematic top view of the optoelectronic packaging structure according to the first embodiment of the present disclosure, while FIG. 4 is a schematic cross-sectional view taken along line IV-IV of FIG. 3. In the present disclosure, the encapsulation structure 5 includes a first packaging part 51 and a second packaging part 52. That is, the encapsulation structure 5 is a double molding structure formed by the first packaging part 51 and the second packaging part 52. The first packaging part 51 covers the sensing component 2 and the light-emitting component. The first packaging part 51 is divided by the first partition wall 4 into a first portion 511 and a second portion 512. The first portion 511 and the second portion 512 are spaced apart from and not in contact with each other. The light-emitting component (i.e., the two light-emitting elements 3) is encapsulated within the first portion 511, while the sensing component 2 is encapsulated within the second portion 512.

One portion of the second packaging part 52 forms an annular perimeter wall 521, while another portion of the second packaging part 52 forms a second partition wall 522. The annular perimeter wall 521 and the second partition wall 522 can be an integrated molded structure. Two ends of the second partition wall 522 are connected to both inner side surfaces of the annular perimeter wall 521 and are located between the light-emitting component and the sensing component 2. More specifically, the first packaging part 51 is also divided by the second partition wall 522 into the first portion 511 and the second portion 512. As shown in FIG. 2, the annular perimeter wall 521 and the second partition wall 522 jointly define a first compartment and a second compartment. The first compartment has a first opening P1, while the second compartment has a second opening P2. The light-emitting component (i.e., the two light-emitting elements 3) and the first portion 511 are located in the first compartment, and the sensing component 2 and the second portion 512 are located in the second compartment. Moreover, the annular perimeter wall 521 is disposed on the substrate 1 and surrounds and directly contacts the first packaging part 51, the light-emitting component, the sensing component 2, and the first partition wall 4. The second partition wall 522 is stacked above the first partition wall 4 and located between the light-emitting component and the sensing component 2. In other words, the first partition wall 4 and the second partition wall 522 jointly form a blocking wall structure to separate the light-emitting component and the sensing component 2.

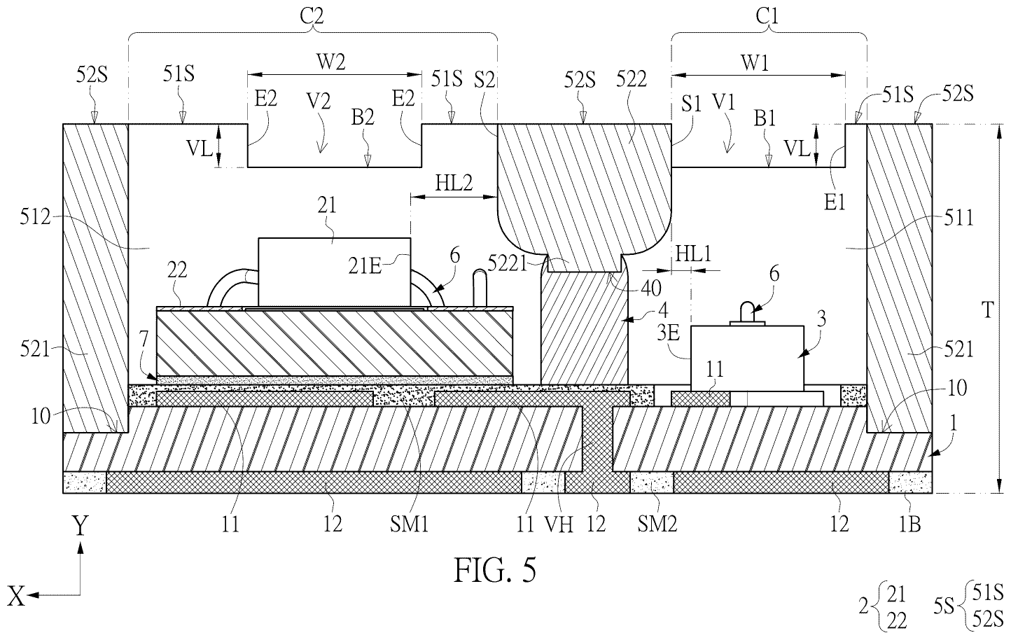

Reference is made to FIG. 5, which is a schematic cross-sectional view of another implementation of the optoelectronic packaging structure according to the first embodiment of the present disclosure. In one embodiment, the second partition wall 522 can be a T-shaped structure with an extending portion 5221, while the surface of the first partition wall 4 forms a recess 40 inwardly recessed toward the substrate 1. Therefore, the way of stacking the first partition wall 4 and the second partition wall 522 can be achieved by engaging the extending portion 5221 of the second partition wall 522 with the recess 40 of the first partition wall 4. Specifically, the encapsulation structure 5 covers the sensing component 2 (i.e., the sensing element 21 and the carrier 22), the light-emitting component (i.e., the two light-emitting elements 3), and the first partition wall 4. In the first direction (i.e., the X-axis direction), a width of the second partition wall 522 is greater than a width of the first partition wall 4. By increasing the width of the second partition wall 522, stray light from the emission end can be prevented from penetrating the second partition wall 522 and entering the sensing end, which can significantly reduce crosstalk effect between the emitted light and the received light during measurement. In the present disclosure, the first packaging part 51 is made of a transparent material or translucent material, while the second packaging part 52 (i.e., the annular perimeter wall 521 and the second partition wall 522) is made of an opaque material. Therefore, the first packaging part 51 is a transparent or translucent structure, and the second packaging part 52 is an opaque structure. Furthermore, both the second partition wall 522 and the first partition wall 4 are made of opaque materials. The materials used for both the second partition wall 522 and the first partition wall 4 can be the same or different, and the present disclosure is not limited thereto.

As shown in FIGS. 1 and 4, a top surface 5S of the encapsulation structure 5 provides a first light-transmissive window C1 and a second light-transmissive window C2, the first light-transmissive window C1 and the second light-transmissive window C2 correspond to the light-emitting component and the sensing component 2, respectively. As shown in FIGS. 2 and 3, the second packaging part 52 has the first opening P1 and the second opening P2 respectively corresponding to the first portion 511 and the second portion 512 of the first packaging part 51. When the first packaging part 51 and the second packaging part 52 form a double molding structure, which is the encapsulation structure 5, the first portion 511 and the second portion 512 fill the first compartment and the second compartment, respectively, and seal the first opening P1 and the second opening P2. Consequently, the top surface 5S of the encapsulation structure 5 is composed of a top surface 52S of the second packaging part 52 and an exposed top surface 51S of the first packaging part 51.

Referring to FIGS. 1 and 4, in the present disclosure, the top surface 5S of the encapsulation structure 5 is a non-planar surface. For example, the top surface 5S is formed with two groove structures at the locations of the top surface 51S of the first portion 511 and the top surface 51S of the second portion 512, specifically a first groove structure V1 and a second groove structure V2. The extension direction of the first groove structure V1 is parallel to the extension direction of the second groove structure V2. As shown in FIG. 4, an exposed surface of the first packaging part 51 includes the top surface 51S, a bottom surface B1 and a side surface E1 of the first groove structure V1, as well as a bottom surface B2 and two side surfaces E2 of the second groove structure V2. Furthermore, the bottom surface B1, the side surface E1, and a first side surface S1 of the second partition wall 522 jointly form the first groove structure V1. The bottom surface B2 and two side surfaces E2 jointly form the second groove structure V2. The first groove structure V1 is formed within the region of the first light-transmissive window C1, while the second groove structure V2 is formed within the region of the second light-transmissive window C2, such that the encapsulation structure 5 includes a non-planar top surface (i.e., the top surface 5S). The first groove structure V1 and the second groove structure V2 correspond to the light-emitting component (i.e., the two light-emitting elements 3) and the sensing component 2, respectively. More specifically, the first light-transmissive window C1 refers to the top area of the first portion 511 of the first packaging part 51 (including the top surface 51S, as well as the bottom surface B1 and the side surface E1 of the first groove structure V1), while the second light-transmissive window C2 refers to the top area of the second portion 512 of the first packaging part 51 (including the top surface 51S, as well as the bottom surface B2 and the two side surfaces E2 of the second groove structure V2).

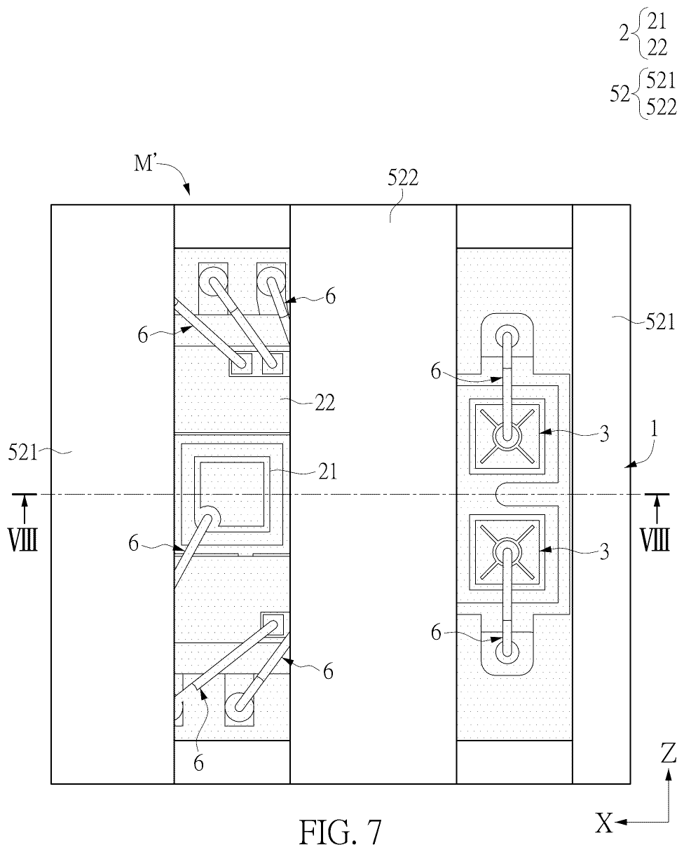

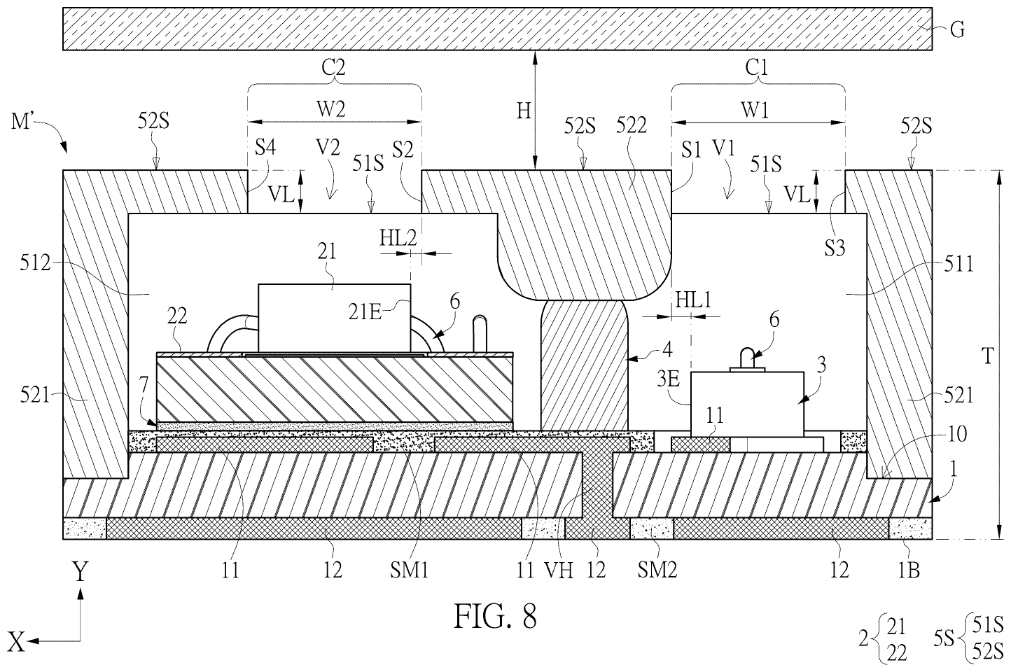

As shown in FIG. 1, for example, each of the first groove structure V1 and the second groove structure V2 has a substantially rectangular shape with a length measured in the second direction (i.e., the Z-axis direction) and a width measured in the first direction (i.e., the X-axis direction). Referring to FIGS. 1 and 4, the first groove structure V1 and the second groove structure V2 may be formed by recessing the top surface 51S of the first packaging part 51 and/or the top surface 52S of the second packaging part 52 downward, thereby forming air gaps. Each of the first groove structure V1 and the second groove structure V2 may penetrate through portions of the two opposite sidewalls of the annular perimeter wall 521 and the first packaging part 51 along the second direction (i.e., the Z-axis direction). As shown in FIGS. 3 and 4, the second direction is perpendicular to the first direction. However, the contour shapes of the first groove structure V1 and the second groove structure V2 are not limited in the present disclosure. In other embodiments, an orthographic projection of each of the groove structures can have a substantially circular, semicircular, elliptical, or other geometric shapes. The orthographic projection of the groove structure may also be a substantially rectangular structure. Furthermore, as shown in FIGS. 7 and 8, the side surfaces of the groove structure are not exposed. Similarly, the shapes of the first light-transmissive window C1 and the second light-transmissive window C2 can have a substantially rectangular, circular, or other geometric shapes. Contour shapes of the first light-transmissive window C1 and the second light-transmissive window C2 are not limited in the present disclosure.

As shown in FIG. 4, a vertical distance VL along a third direction (i.e., a Y-axis direction) is defined between the bottom surface B1 of the first groove structure V1 (i.e., the exposed top surface of the first packaging part 51) and the top surface 52S of the second packaging part 52, as well as between the bottom surface B2 of the second groove structure V2 and the top surface 52S of the second packaging part 52. The vertical distance VL is defined as the depth of each of the first groove structure V1 and the second groove structure V2. Additionally, the overall height of the optoelectronic packaging structure M can be defined as a maximum predetermined height T between the top surface 52S of the second packaging part 52 and a bottom surface 1B of the substrate 1. The vertical distance VL (i.e., the depth of each of the first groove structure V1 and the second groove structure V2) is 5% to 40% of the maximum predetermined height T.

The optoelectronic packaging structure M in the present disclosure forms a non-planar structure on its top surface 5S, specifically forming the first groove structure V1 and the second groove structure V2. Through the air gaps formed by the first groove structure V1 and the second groove structure V2, the light's travel path can be increased due to the added vertical distance VL, thereby enlarging the distance from the external transparent cover (e.g., the glass G shown in FIG. 8) to the light-emitting component and the sensing component 2, helping reduce the likelihood of stray light entering the sensor (i.e., the optoelectronic packaging structure), minimizing crosstalk and improving product reliability.

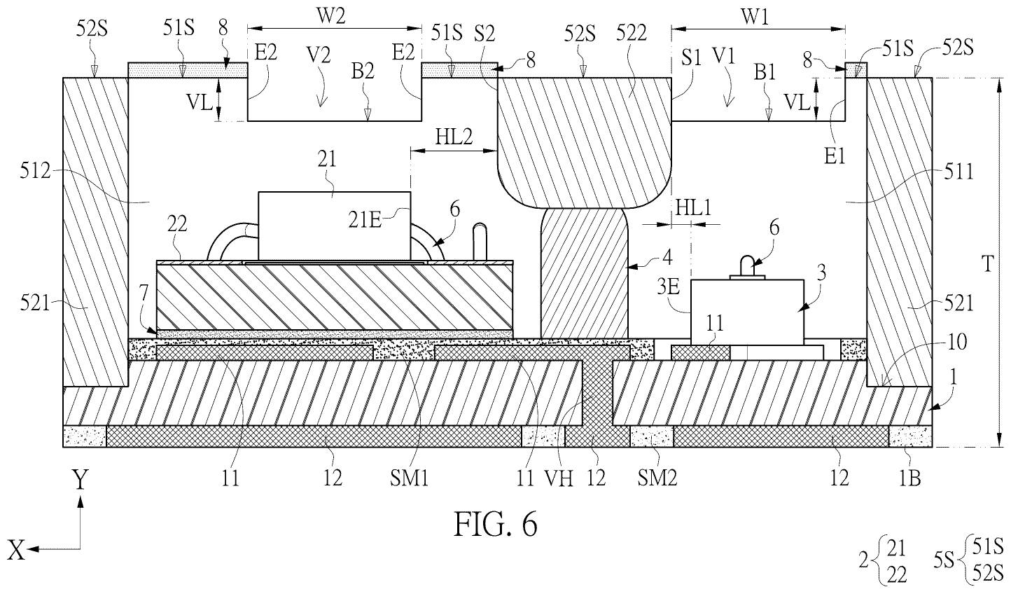

As shown in FIG. 6, a light-shielding layer 8, such as a black ink, can be applied to cover the top surface 51S of the first packaging part 51, excluding the first groove structure V1 and the second groove structure V2 (i.e., the first groove structure V1 and the second groove structure V2 are not covered by the light-shielding layer 8), to further prevent the sensing component 2 from being affected by ambient light or stray light, which can cause optical crosstalk. In other embodiments, the light-shielding layer 8 can further extend to cover the top surface 52S of the second packaging part 52.

Reference is further made to FIG. 4. The first groove structure V1 has a first width W1. An inner edge of the first groove structure V1 close to the second partition wall 522 is aligned with the first side surface S1 of the second partition wall 522. In the X-axis direction, the side edge 3E of the light-emitting element 3 does not extend beyond the first side surface S1. The first side surface S1 is also the edge of the first light-transmissive window C1. That is, the first side surface S1 and the side edge 3E of the light-emitting element 3 can be substantially aligned or have a predetermined distance therebetween.

Specifically, a first horizontal distance HL1 is defined between the first side surface S1 and the side edge 3E of the light-emitting element 3. The first horizontal distance HL1 is not greater than 25% of the first width W1. In other words, the first horizontal distance HL1 is 0% to 25% of the first width W1. When the first horizontal distance HL1 is 0, the first side surface S1 is aligned with the side edge 3E of the light-emitting element 3.

Additionally, in the first direction, the second groove structure V2 has a second width W2, and a second horizontal distance HL2 is defined between a side edge 21E of the sensing element 21 of the sensing component 2 and a second side surface S2 of the second partition wall 522. The second horizontal distance HL2 is not greater than 25% of the second width W2. In the present disclosure, the second horizontal distance HL2 may be longer than the first horizontal distance HL1, but the present disclosure is not limited thereto.

By designing the first horizontal distance HL1 (the distance between the side edge 3E of the light-emitting element 3 and the edge of the first light-transmissive window C1) and the second horizontal distance HL2 (the distance between the side edge 21E of the sensing element 21 and the edge of the second light-transmissive window C2), the positions of the light-emitting element 3 and the sensing component 2 can be controlled to ensure they are not too far from the blocking wall structure. This design prevents the light emitted from the light-emitting component through the first light-transmissive window C1 from diffracting due to contact with the transparent cover (i.e., the glass G shown in FIG. 8) before reaching the object to be detected. Such diffraction could cause some light to prematurely enter the second light-transmissive window C2 and be received by the sensing component 2, thereby affecting the accuracy of the sensing results.

### Second Embodiment

Reference is made to FIG. 7 and FIG. 8. FIG. 7 is a schematic top view of an optoelectronic packaging structure according to a second embodiment of the present disclosure. FIG. 8 is a schematic cross-sectional view taken along line VIII-VIII of FIG. 7. The second embodiment of the present disclosure provides an optoelectronic packaging structure M′, which includes a substrate 1, a sensing component 2, a light-emitting component, a first partition wall 4, and an encapsulation structure 5.

The optoelectronic package structure M′ of the second embodiment has a structure similar to the optoelectronic package structure M of the first embodiment, and the similarities will not be reiterated herein. The main difference between the second embodiment and the first embodiment is as follows: the encapsulation structure 5 and the range of the first and second light-transmissive windows C1 and C2 of the optoelectronic packaging structure M′ of the second embodiment are different from those in the first embodiment. Specifically, in the second embodiment, a top surface of the annular perimeter wall 521 of the second packaging part 52 and a top surface of the second partition wall 522 at least partially extend to cover at least a portion of the top surface 51S of the first packaging part 51. In other words, the orthographic projection of the top surface 52S of the second package part 52 on the substrate 1 partially overlaps with the orthographic projection of the top surface 51S of the first package part 51 on the substrate 1, while the regions of the top surface 51S of the first packaging part 51 not covered by the second packaging part 52 respectively form the first and second light-transmissive windows C1 and C2. Additionally, the exposed top surface 51S of the first packaging part 51 and the upper end of the second packaging part 52 jointly define the first groove structure V1 and the second groove structure V2. In other words, the exposed top surface 51S of the first portion 511 of the first packaging part 51, the first side surface S1 of the second partition wall 522 and a first inner edge surface S3 of the annular perimeter wall 521 jointly define the first groove structure V1. The exposed top surface 51S of the second portion 512 of the first packaging part 51, the second side surface S2 of the second partition wall 522 and a second inner edge surface S4 of the annular perimeter wall 521 jointly define the second groove structure V2.

A vertical distance VL along a third direction (i.e., a Y-axis direction) is defined between the bottom surface (i.e., the exposed top surface 51S of the first portion 511 of the first packaging part 51) of the first groove structure V1 and the top surface 52S of the second packaging part 52, as well as between the bottom surface (i.e., the exposed top surface 51S of the second portion 512 of the first packaging part 51) of the second groove structure V2 and the top surface 52S of the second packaging part 52. The vertical distance VL is defined as the depth of each of the first groove structure V1 and the second groove structure V2. Additionally, the overall height of the optoelectronic packaging structure M′ is defined as the maximum predetermined height T between the top surface 52S of the second packaging part 52 and the bottom surface 1B of the substrate 1. The vertical distance VL (i.e., the depth of the first groove structure V1 and the second groove structure V2) is 5% to 40% of the maximum predetermined height T.

The first groove structure V1 has a first width W1. In the X-axis direction, the side edge 3E of the light-emitting element 3 does not extend beyond the first side surface S1 of the second partition wall 522. That is, the first side surface S1 and the side edge 3E of the light-emitting element 3 can be substantially aligned or have a predetermined distance therebetween.

Specifically, the first horizontal distance HL1 is defined between the first side surface S1 of the second partition wall 522 and the side edge 3E of the light-emitting element 3. The first horizontal distance HL1 is not greater than 25% of the first width W1. In other words, the first horizontal distance HL1 is 0% to 25% of the first width W1. When the first horizontal distance HL1 is 0, the first side surface S1 is aligned with the side edge 3E of the light-emitting elements 3.

Similarly, the second groove structure V2 has a second width W2, and a second horizontal distance HL2 is defined between a side edge 21E of the sensing element 21 of the sensing component 2 and the second side surface S2 of the second partition wall 522. The second horizontal distance HL2 is not greater than 25% of the second width W2.

Furthermore, in this embodiment, the first light-transmissive window C1 is completely located within the first groove structure V1, and the second light-transmissive window C2 is completely located within the second groove structure V2. In other words, the orthographic projection of the first light-transmissive window C1 on the substrate 1 at least covers the orthographic projection of the bottom surface B1 (i.e., the exposed top surface 51S) of the first groove structure V1 on the substrate 1, and the orthographic projection of the second light-transmissive window C2 on the substrate 1 at least covers the orthographic projection of the bottom surface B2 (i.e., the exposed top surface 51S) of the second groove structure V2 on the substrate 1. The contour shapes of the first groove structure V1 and the second groove structure V2 are not limited in the present disclosure. For example, as shown in FIG. 7, both the first groove structure V1 and the second groove structure V2 have substantially rectangular shape with a width measured in the first direction (i.e., the X-axis direction) and a length measured in the second direction (i.e., the Z-axis direction). However, in other embodiments, the orthographic projection of the groove structure can have a substantially circular, semicircular, elliptical, or other shapes. Similarly, the shapes of the first light-transmissive window C1 and the second light-transmissive window C2 can have a substantially rectangular, circular, or other shapes. The contour shapes of the first light-transmissive window C1 and the second light-transmissive window C2 are not limited in the present disclosure.

In the process of manufacturing the optoelectronic packaging structure M′, the sensing component 2 and the light-emitting component (at least one light-emitting element 3) are placed on the substrate 1. Then, a first opaque material is applied between the light-emitting component and the sensing component 2 by dispensing, such that the first partition wall 4 is formed. Then, a transparent material or translucent material, which is the first packaging part 51, is encapsulated on the substrate 1, preferably by an injection-molding process, to cover the sensing component 2, the light-emitting component, and the first partition wall 4. Afterwards, the outer peripheral part of the first packaging part 51 and the part of the first packaging part 51 located above the first partition wall 4 are removed to form some accommodating spaces.

In other embodiments, during the step of removing parts of the first packaging part 51, in addition to removing the outer peripheral part of the first packaging part 51, it may even cut into the corresponding part of the upper surface of the substrate 1 to form a first trench 10 at the outer edge of the upper surface of the substrate 1, the annular perimeter wall 521 is inserted into the first trench 10, and an outer surface of the annular perimeter wall 521 is aligned with an outer periphery of the substrate 1. For example, the upper surface of the substrate 1 can be formed with a stepped structure. Furthermore, during the step of removing parts of the first packaging part 51, in addition to removing the part of the first packaging part 51 above the first partition wall 4, the upper part of the first partition wall 4 can also be partially removed to form a second trench 40, thereby increasing the volume of the accommodating space (as shown in FIG. 5). Next, a second opaque material, for example, may be fabricated by a molding process, such as injection molding, is filled into these accommodating spaces and covers the first packaging part 51. The second opaque material that is surrounded around the outer side of the first packaging part 51 forms the annular perimeter wall 521 of the second packaging part 52. The second opaque material filled above the first partition wall 4 forms the second partition wall 522. Then, portions of the second opaque material corresponding to the positions above the sensing component 2 and the light-emitting component are removed to form the first groove structure V1 and the second groove structure V2. The location of the first groove structure V1 corresponds to the first light-transmissive window C1, and the location of the second groove structure V2 corresponds to the second light-transmissive window C2.

### Beneficial Effects of the Embodiments

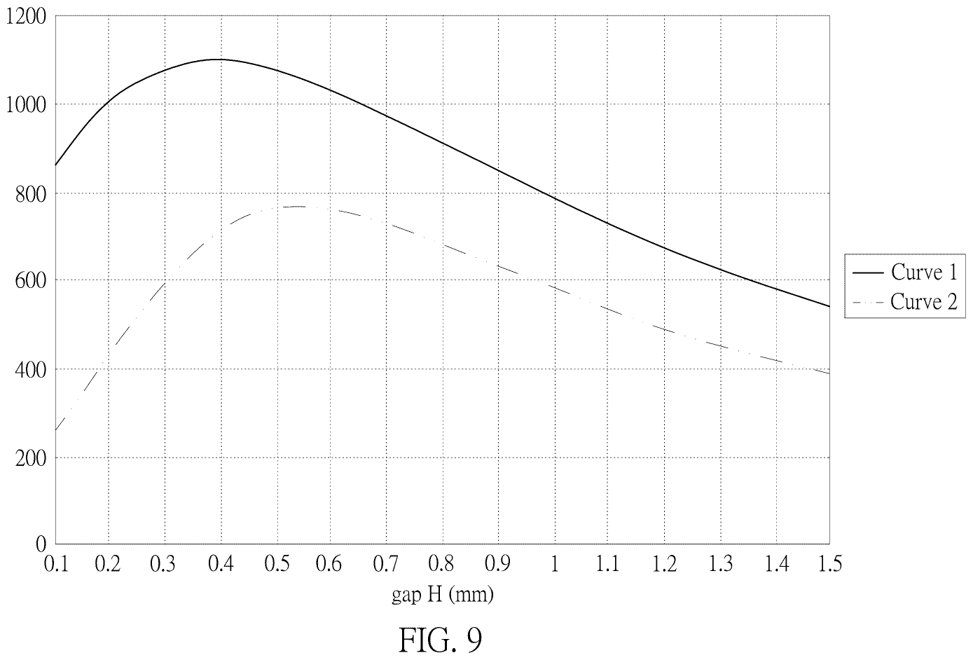

Reference is made to FIGS. 8 and 9, FIG. 9 is a curve diagram showing the test result of the optoelectronic packaging structure according to the present disclosure. FIG. 8 shows the relative location between the transparent cover (e.g., the glass G) and the optoelectronic packaging structure M′ that is installed inside an electronic device (not shown in the figures). For example, the electronic device may be a wearable device configured with an optical sensor module. The glass G is located above the optoelectronic packaging structure (M, M′), and the optoelectronic packaging structure and the glass G are spaced apart from each other by a gap H. Curve 1 in FIG. 9 represents a traditional optoelectronic packaging structure that has a flat top surface (i.e., no air gaps). That is, the vertical distance VL is equal to 0 in FIG. 8 (i.e., the top surface 51S of the first packaging part 51 is completely aligned with the top surface 52S of the second packaging part 52). Curve 2 in FIG. 9 represents the optoelectronic packaging structure M′ of the present disclosure, which includes first and second groove structures (V1, V2) with predetermined depth (i.e., having air gaps). That is, the vertical distance VL of the present disclosure is not equal to 0 in FIG. 8. It should be noted that the horizontal axis in FIG. 9 represents the gap H, while the vertical axis represents the digital count of the electronic device with the optical sensor. The digital count refers to the number of changes in digital signals measured by the optical sensor over a certain time period. It reflects changes in, for example, light intensity detected by the optical sensor and is usually related to the resolution or accuracy of the optical sensor.

By measuring the crosstalk values when the glass G is at different distances above the optoelectronic packaging structure (with the gap H gradually increasing from 0.1 mm to 1.5 mm), it can be observed that the crosstalk of the optoelectronic packaging structure M′ is significantly reduced. This improvement is due to the optoelectronic packaging structure M′ forming the non-planar structure formed on its top surface, which includes the first groove structure V1 and the second groove structure V2. The air gaps formed by the first groove structure V1 and the second groove structure V2 lengthen the light travel path (due to the vertical distance VL added). As a result, the distance between the light-emitting component and the external transparent cover (i.e., the glass G shown in FIG. 8), as well as between the sensing component 2 and the external transparent cover, can be increased, thereby reducing the likelihood of the stray light entering the optical sensor. Therefore, by comparing Curve 2 with Curve 1 in FIG. 9, it can be seen that because stray light is less likely to enter the sensing component 2 of the present disclosure, the digital count measured by the sensing component 2 of the present disclosure is significantly reduce compared to the traditional optoelectronic packaging structure, thereby reducing crosstalk and improving product reliability.

Furthermore, by designing the first horizontal distance HL1 and the second horizontal distance HL2, the distances between the light-emitting component and the edge of the first light-transmissive windows C1, as well as between the sensing component 2 and the edge of the second light-transmissive windows C2, can be controlled to ensure that the light-emitting component (at least one of the light-emitting elements 3) and the sensing component 2 are not too far from the blocking wall structure. This design prevents the light emitted from the light-emitting component through the first light-transmissive window C1 from diffracting due to contact with the transparent cover (i.e., the glass G shown in FIG. 8) before reaching the object to be detected such diffraction could cause some light to prematurely enter the second light-transmissive window C2 and be received by the sensing component 2, thereby affecting the accuracy of the sensing results.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An optoelectronic packaging structure, comprising:
a substrate;
a sensing component disposed on the substrate;
a light-emitting component disposed on the substrate, wherein the sensing component and the light-emitting component are arranged along a first direction;
a first partition wall disposed on the substrate and located between the sensing component and the light-emitting component, wherein the first partition wall extends along a second direction; and
an encapsulation structure disposed on the substrate and covering the sensing component, the light-emitting component, and the first partition wall;
wherein a portion of a top surface of the encapsulation structure defines a first light-transmissive window and a second light-transmissive window, and a first groove structure and a second groove structure corresponding to the light-emitting component and the sensing component are formed within regions of the first light-transmissive window and the second light-transmissive window, respectively, such that the encapsulation structure includes a non-planar top surface.

2. The optoelectronic packaging structure according to claim 1, wherein the encapsulation structure includes a first packaging part and a second packaging part, the first packaging part covers the sensing component and the light-emitting component, a portion of the second packaging part forms an annular perimeter wall to surround the first packaging part, the sensing component, the light-emitting component, and the first partition wall, and another portion of the second packaging part forms a second partition wall to be stacked above the first partition wall.

3. The optoelectronic packaging structure according to claim 2, wherein the first packaging part is divided into a first portion and a second portion by the first partition wall, the first portion and the second portion are spaced apart from and not in contact with each other, the light-emitting component is encapsulated within the first portion, and the sensing component is encapsulated within the second portion.

4. The optoelectronic packaging structure according to claim 2, wherein the non-planar top surface of the encapsulation structure is formed by a top surface of the second packaging part and an exposed surface of the first packaging part that is exposed from the second packaging part.

5. The optoelectronic packaging structure according to claim 2, wherein a vertical distance is defined between a bottom surface of the first groove structure and the top surface of the second packaging part, a maximum predetermined height is defined between the top surface of the second packaging part and a bottom surface of the substrate, and the vertical distance is 5% to 40% of the maximum predetermined height.

6. The optoelectronic packaging structure according to claim 2, wherein the first groove structure extends along the second direction and penetrates through portions of two opposite sidewalls of the annular perimeter wall, and the second direction is perpendicular to the first direction.

7. The optoelectronic packaging structure according to claim 2, wherein an inner edge of the first groove structure is aligned with a first side surface of the second partition wall.

8. The optoelectronic packaging structure according to claim 1, wherein the first groove structure has a first width in the first direction, a first horizontal distance is defined between an edge of the first light-transmissive window and an edge of the light-emitting component, and the first horizontal distance is not greater than 25% of the first width.

9. The optoelectronic packaging structure according to claim 1, wherein the second groove structure has a second width along the first direction, a second horizontal distance is defined between a second side surface of the second groove structure and a side edge of the sensing component, and the second horizontal distance is not greater than 25% of the second width.

10. The optoelectronic packaging structure according to claim 6, wherein the second groove structure extends along the second direction and penetrates through portions of two opposite sidewalls of the annular perimeter wall, the second direction is perpendicular to the first direction, and an extension direction of the first groove structure is parallel to an extension direction of the second groove structure.

11. The optoelectronic packaging structure according to claim 2, wherein a width of the second partition wall in the first direction is greater than a width of the first partition wall in the first direction.

12. The optoelectronic packaging structure according to claim 2, wherein the first packaging part and the second packaging part of the encapsulation structure jointly form a double molding structure.

13. The optoelectronic packaging structure according to claim 2, wherein a first trench is formed at an outer edge of an upper surface of the substrate, the annular perimeter wall is inserted into the first trench, and an outer surface of the annular perimeter wall is aligned with an outer periphery of the substrate.

14. The optoelectronic packaging structure according to claim 2, further comprising a light-shielding layer that covers a top surface of the first packaging part, wherein the first groove structure and the second groove structure are not covered by the light-shielding layer.

15. An optoelectronic packaging structure, comprising:
a substrate;
a sensing component disposed on the substrate;
a light-emitting component disposed on the substrate, wherein the sensing component and the light-emitting component are arranged along a first direction;
a first partition wall disposed on the substrate and located between the sensing component and the light-emitting component, wherein the first partition wall extends along a second direction; and
an encapsulation structure disposed on the substrate, wherein the encapsulation structure includes a first packaging part and a second packaging part, the sensing component and the light-emitting component are encapsulated within the first packaging part, a portion of the second packaging part forms an annular perimeter wall surrounding the first packaging part, and another portion of the second packaging part forms a second partition wall stacked above the first partition wall, wherein first partition wall and the second partition wall jointly divide the first packaging part into a first portion and a second portion;
wherein a portion of a top surface of the first packaging part exposed by the second packaging part defines a first light-transmissive window and a second light-transmissive window corresponding to the light-emitting component and the sensing component;
wherein a vertical distance is defined between the exposed portion of the top surface of the first packaging part and a top surface of the second packaging part, a maximum predetermined height is defined between the top surface of the second packaging part and a bottom surface of the substrate, and the vertical distance is 5% to 40% of the maximum predetermined height.

16. An optoelectronic packaging structure, comprising:
a substrate;
a sensing component disposed on the substrate;
a light-emitting component disposed on the substrate, wherein the sensing component and the light-emitting component are arranged along a first direction;
a first partition wall disposed on the substrate and located between the sensing component and the light-emitting component, wherein the first partition wall extends along a second direction; and
an encapsulation structure disposed on the substrate, wherein the encapsulation structure includes a first packaging part and a second packaging part, the first packaging part covers the light-emitting component and the sensing component, a portion of the second packaging part forms an annular perimeter wall to surround and directly contact the first packaging part and the first partition wall, and another portion of the second packaging part forms a second partition wall stacked above the first partition wall, wherein the first partition wall and the second partition wall jointly divide the first packaging part into a first portion and a second portion;
wherein the encapsulation structure includes a non-planar top surface, a portion of a top surface of the first packaging part exposed by the second packaging part defines a first light-transmissive window and a second light-transmissive window, corresponding to the light-emitting component and the sensing component, respectively;
wherein a width of the second partition wall in the first direction is greater than a width of the first partition wall in the first direction.

17. The optoelectronic packaging structure according to claim 16, wherein the top surface of the encapsulation structure is formed with a first groove structure within a region of the first light-transmissive window, the top surface of the encapsulation structure is formed with a second groove structure within a region of the second light-transmissive window, and the first groove structure and the second groove structure extend in a same direction and penetrate through portions of two opposite sidewalls of the annular perimeter wall.

18. The optoelectronic packaging structure according to claim 16, wherein a top surface of the annular perimeter wall and a top surface of the second partition wall at least partially extend to cover at least a portion of the top surface of the first packaging part.

19. An electronic device, comprising:
a transparent cover; and
the optoelectronic packaging structure as claimed in claim 1, wherein the optoelectronic packaging structure and the transparent cover are spaced apart from each other by a gap.

20. An electronic device, comprising:
a transparent cover; and
the optoelectronic packaging structure as claimed in claim 15, wherein the optoelectronic packaging structure and the transparent cover are spaced apart from each other by a gap.

21. An electronic device, comprising:
a transparent cover; and
the optoelectronic packaging structure as claimed in claim 16, wherein the optoelectronic packaging structure and the transparent cover are spaced apart from each other by a gap.
